(19) United States
(12) Patent Application Publication
(10) Pub. No.: US 2015/0004312 A1
(43) Pub. Date: Jan. 1, 2015

(54) ADJUSTABLE MASK

(71) Applicant: APPLIED MATERIALS, INC., Santa Clara, CA (US)

(72) Inventors: Evelyn Scheer, Stockstadt (DE); Markus Hanika, Landsberg (DE); Ralph Lindenberg, Budingen-Rinderbugen (DE); Marcus Bender, Hanau (DE); Andreas Lopp, Freigericht (DE); Konrad Schwanitz, Aschaffenburg (DE); Fabio Pieralisi, Aschaffenburg (DE); Jian Liu, Grosskrotzenburg (DE)

(73) Assignee: APPLIED MATERIALS, INC., Santa Clara, CA (US)

(21) Appl. No.: 14/237,158

(22) PCT Filed: Aug. 9, 2011
(86) PCT No.: PCT/EP2011/063714

§ 371 Date: Sep. 10, 2014

(51) Int. Cl. C23C 14/04; C23C 16/04

(52) U.S. Cl. CPC C23C 14/042; C23C 16/042
USPC 427/248.1; 118/720

(57) ABSTRACT

An deposition apparatus for forming a deposition material layer on a substrate is described. The deposition apparatus includes a substrate support adapted for holding a substrate; and an edge (660) exclusion mask (640) for covering a periphery of the substrate (610) during layer deposition. The mask has at least one frame portion defining an aperture. The at least one frame portion of the mask is adapted for being moved (670,680) with respect to the substrate depending on the amount of deposition material deposited on the at least one frame portion of the mask. Further, a method for depositing a deposition material layer on a substrate using an edge exclusion mask is described.

### TECHNICAL FIELD OF THE INVENTION

Embodiments of the present invention relate to a deposition apparatus and a method of depositing material on a substrate. Embodiments of the present invention particularly relate to a deposition apparatus having a mask for a substrate to be treated with the deposition apparatus, a mask for a deposition apparatus, and a method for masking a substrate to be treated. Specifically, embodiments refer to an edge exclusion mask and a method for masking the edges of a substrate.

### BACKGROUND OF THE INVENTION

Several methods are known for depositing a material on a substrate. For instance, substrates may be coated by a physical vapor deposition (PVD) process, a chemical vapor deposition (CVD) process, a plasma enhanced chemical vapor deposition (PECVD) process etc. Typically, the process is performed in a process apparatus or process chamber, where the substrate to be coated is located. A deposition material is provided in the apparatus. In case, where a PVD process is performed, the deposition material may for instance be in the gaseous phase. A plurality of materials may be used for deposition on a substrate. Among them, many different metals can be used, but also oxides, nitrides or carbides. Typically, a PVD process is suitable for thin film coatings.

Coated materials may be used in several applications and in several technical fields. For instance, an application lies in the field of microelectronics, such as generating semiconductor devices. Also, substrates for displays are often coated by a PVD process. Further applications include insulating panels, organic light emitting diode (OLED) panels, but also hard disks, CDs, DVDs and the like.

In coating processes, it may be useful to use masks, for instance, in order to better define the area to be coated. In some applications, only parts of the substrate should be coated and the parts not to be coated are covered by a mask. In some applications, such as in large area substrate coating apparatuses, it is desirable to exclude the edge of the substrate from being coated. With the edge exclusion, it is possible to provide coating free substrate edges and to prevent a coating of the backside of the substrate.

However, the mask in a material deposition process, which may be an edge exclusion mask, is also exposed to the deposition material due to the location of the mask in front of the substrate. Thus, deposition material accumulates on the surface of the mask during processing. This can result in a modified contour of the mask due to the material deposited on the mask. For instance, the periphery or boundary of a mask aperture may be reduced with a growing deposition material layer on the mask. Often, a cleaning procedure of the mask is performed for assuring the exact dimensions of the area covered by the mask. This cleaning procedure interrupts the material deposition process and is therefore time and cost intensive.

In view of the above, it is an object of the present invention to provide a mask, particularly an edge exclusion mask, a deposition apparatus having a mask, and a method of masking the edges of a substrate that overcome at least some of the problems in the art.

### SUMMARY OF THE INVENTION

In light of the above, an apparatus for forming a deposition material layer according to independent claim 1, a method for depositing a deposition material layer according to independent claim 9, and an edge exclusion mask for a deposition apparatus according to claim 14 are provided. Further aspects, advantages, and features of the present invention are apparent from the dependent claims, the description, and the accompanying drawings.

According to one embodiment, a deposition apparatus for forming a deposition material layer on a substrate is provided. The deposition apparatus includes a substrate support, which is adapted for holding a substrate. Further, the deposition apparatus includes an edge exclusion mask for covering a periphery of a substrate during layer deposition. The mask has at least one frame portion defining an aperture, wherein the at least one frame portion of the mask is adapted for being moved with respect to the substrate depending on the amount of deposition material deposited on the at least one frame portion of the mask.

According to another embodiment, a method for depositing a deposition layer on a substrate is provided. The method includes providing a substrate in a deposition apparatus and covering at least a part of the substrate with a mask. The mask includes at least one frame portion defining an aperture. Further, the method includes moving the at least one frame portion of the mask with respect to the substrate depending on the amount of deposition material deposited on the at least one frame portion of the mask.

According to another embodiment, an edge exclusion mask for a deposition apparatus for depositing a deposition material layer on a substrate is provided. Typically, the mask is adapted for covering a periphery of the substrate, and includes at least one frame portion defining an aperture for allowing deposition material passing through onto the substrate; wherein the at least one frame portion of the mask is adapted for being moved with respect to the substrate depending on the amount of deposition material deposited on the at least one frame portion of the mask

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a substrate according to embodiments described herein;

FIG. 2 shows a schematic view of a material deposition apparatus having an edge exclusion mask;

FIG. 3 shows a schematic perspective view of a substrate and an edge exclusion mask as known in the art;

FIG. 4 shows a schematic sectional view of an edge exclusion mask;

FIG. 5 shows a schematic top view of an edge exclusion mask according to embodiments described herein;

FIG. 6 shows a schematic top view of an edge exclusion mask during or after operation according to embodiments described herein;

FIG. 7 shows a schematic top view of an edge exclusion mask during or after operation according to embodiments described herein;

FIG. 8 shows a schematic view of a deposition apparatus with an edge exclusion mask according to embodiments described herein; and

FIG. 9 shows a schematic flow chart of a method for depositing a deposition material layer on a substrate according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

An edge exclusion mask is desirable when the edge of a substrate should be kept free from deposition material. This may be the case when only a defined area of the substrate should be coated due to the later application of the coated substrate. For instance, a substrate which will be used as a display part, should have predefined dimensions. Typically, large area substrates are coated using an edge exclusion mask in order to shadow the edge of the substrate and/or to prevent backside coating of the substrate. This approach allows for reliable, constant coating on substrates. Substrates having an edge free of deposition material may be further processed.

According to some embodiments, large area substrates may have a size of typically about 1.4 m² to about 8 m², more typically about 2 m² to about 6 m², and even more typically about 2.5 m² and 5.5 m². For instance, the size of a substrate may correspond to substrates of GEN 5, 6, or even 8.

Typically, a substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

According to some embodiments, the term “mask” is used for a piece of mask material, such as a carbon fiber material or a metal like aluminum, titan, stainless steel or the like. The mask covers a part of the substrate to be coated. Typically, the mask is located between the substrate to be coated and the source of deposition material, such as a crucible, a target or the like. According to some embodiments, an “edge exclusion mask” should be understood as a mask which covers at least an edge of the substrate to be coated. Generally, a mask may be composed of several parts or portions, such as a frame, which defines one or more apertures. The frame of a mask may again have several frame portions or frame parts.

Typically, an edge exclusion mask may cover from about 1% to about 5% of the area of the substrate, typically between about 5% to about 3% and even more typically between about 1% and about 2% of the area of the substrate. According to some embodiments, the area of the substrate covered by the edge exclusion mask is located at the periphery of the substrate.

According to some embodiments, the term “mask aperture” should be understood as a window of a mask, through which the deposition material may pass during the deposition process. Typically, the “mask aperture” may also be denoted as coating window as it defines the area of the substrate on which coating material is deposited. The boundary or the inner boundary of the aperture is defined by the limitation of the coating window. For instance, if the mask is new or freshly cleaned and was not yet used in a deposition process, the boundary of the aperture consist of mask material. If the mask is used in a deposition process and deposition material is deposited on the mask, the boundary of the aperture may be the limitation of the coating window by the deposited material on the mask, as further explained in detail below.

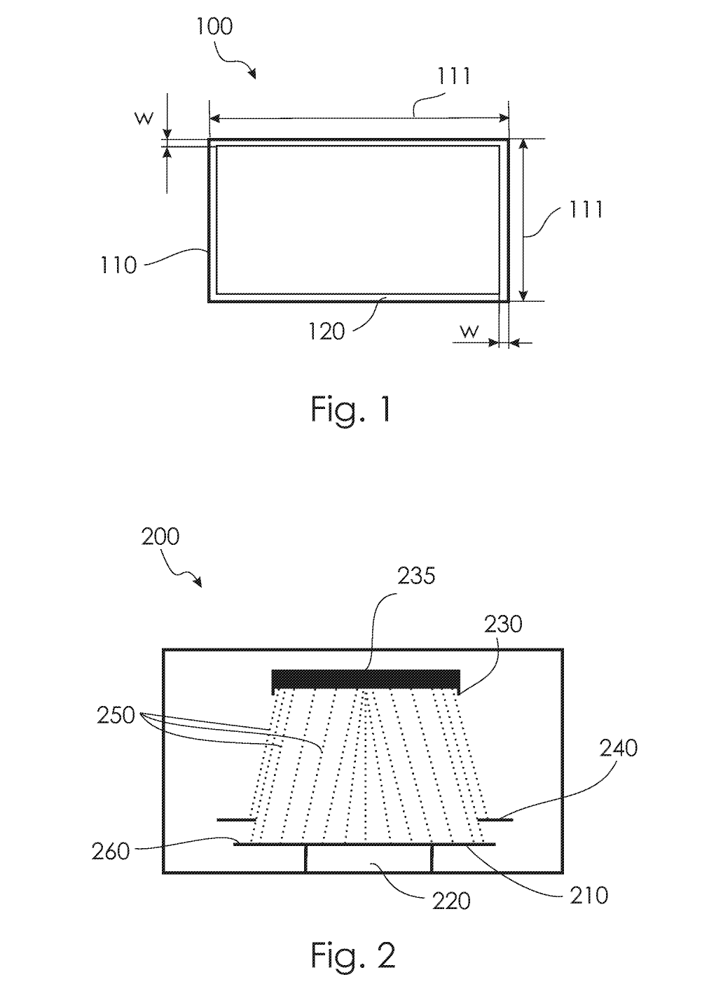

For illustrating the terms used herein, FIG. 1 shows an example of a substrate. The substrate 100 is exemplarily shown in rectangular shape but may also have any other suitable shape. An outermost border of the substrate is denoted with 110. Typically, the border 110 may also be described as the outermost line of the substrate, beyond which the material of the substrate ends. In FIG. 1, the length of a border is denoted with 111.

As used herein and according to some embodiments, an edge 120 of the substrate may contain the periphery of the substrate. Typically, the edge 120 as used herein may be an area containing the border 110 the substrate. According to some embodiments, the edge 120 may have a defined width w, which extends on the surface of the substrate 100 from the border 110.

Typically, the edge may have a width of typically about 1 mm, more typically about 3 mm, and even more typically about 5 mm extending in the surface of the substrate. According to some embodiments, the width w may also be greater than 5 mm, such as 6 mm, 7 mm, or even 10 mm, depending on the desired substrate properties. According to other embodiments, the width w may also be less than 1mm, such as 0.5 mm.

Typically, the width w may be uniform for the whole substrate but may also vary from side to side, depending on the application of the substrate. According to some embodiments, the edge of the substrate may be defined by the aperture of the mask used for coating the substrate. For instance, the aperture of an edge exclusion mask influences the area of the substrate which is coated and covers an area of the substrate such as the edge. Thus, the edge of a substrate may be defined as the area of the substrate which is covered by the edge exclusion mask and which is not coated during the coating process in which the edge exclusion mask is used. Typically, the edge of a substrate may be defined as an area of the substrate which should be kept substantially free of deposition material.

The term “substantially” in this context means that there may be a certain deviation from the characteristic denoted with “substantially.” For instance, “substantially parallel” may include deviations of some degrees, such as 5 or 10 degrees, from the parallel arrangement.

FIG. 2 shows a schematic view of a deposition chamber 200 according to embodiments. The deposition chamber 200 is adapted for a deposition process, such as a PVD or CVD process. A substrate 210 is shown being located on a substrate support 220. According to some embodiments, the substrate support may be movable to allow adjusting the position of the substrate 210 in the chamber 200. Typically, the substrate support 220 may be movable in order to allow for uniform layer deposition, for instance, by rotating. A deposition material source 230 is provided in chamber 200. The deposition material source 230 provides deposition material 235.

In FIG. 2, the source 230 provides the material to be deposited. According to some embodiments, the source 230 may be a target with deposition material thereon or any other arrangement allowing material to be released for deposition on substrate 210.

Typically, the material source 230 may be a rotatable target. According to some embodiments, the material source 230 may be movable in order to position and/or replace the source 230. According to other embodiments, the material source may be a planar target.

According to some embodiments, the deposition material 235 may be chosen according to the deposition process and the later application of the coated substrate. For instance, the deposition material of the source may be a material selected from the group consisting of: a metal, such as aluminum, molybdenum, titanium, copper, or the like, silicon, indium tin oxide, and other transparent conductive oxides. Typically, oxide-, nitride- or carbide-layers, which can include such materials, can be deposited by providing the material from the source or by reactive deposition, i.e. the material from the source reacts with elements like oxygen, nitride, or carbon from a processing gas. According to some embodiments, thin film transistor materials like siliconoxides, siliconoxynitrides, siliconnitrides, aluminumoxide, aluminumoxynitrides may be used as deposition material.

Typically, the deposition chamber 200 includes a mask 240. According to some embodiments, the mask 240 is an edge exclusion mask. The edge exclusion mask 240 ensures that the edges of the substrate 210 are not coated with deposition material 235. Dashed lines 250 show exemplarily the path of the deposition material 235 during operation of the chamber 200. As an example, the material 235 is vaporized and dashed lines 250 show schematically the path of the vapor of the deposition material 235 to the substrate 210.

As can be seen in FIG. 2 by the dashed lines 250, an edge 260 of the substrate 210 remains free of deposition material due to the edge exclusion mask 240.

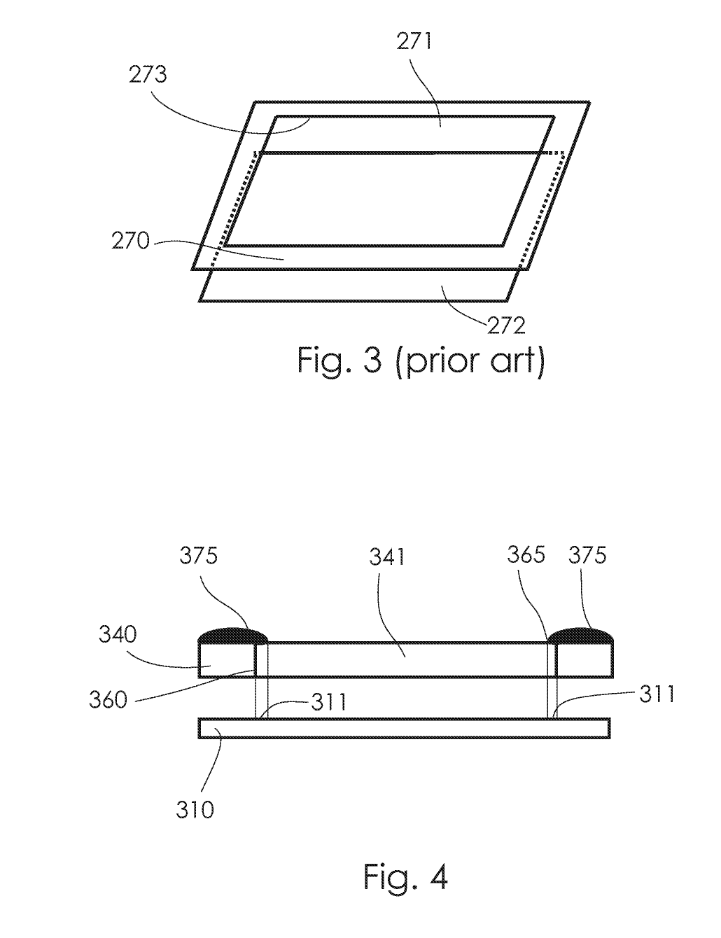

FIG. 3 shows a schematic perspective view of an edge exclusion mask 270 as known in the art. The substrate 272 is shown as being below the mask 270. The mask has an aperture 271 through which material to be deposited on substrate 272 may pass. The aperture 271 is limited by a boundary 273 of the aperture. The area of the aperture 271 is smaller than the area of the substrate 272 so that an edge of the substrate 272 remains free of deposition material.

In a production environment, material is deposited on the substrate but also on the mask partly covering the substrate. When material is deposited on an edge exclusion mask, the size of the aperture may change due to the material deposited on the boundary of the aperture. The consequence of the changed size of the aperture is exemplarily shown in FIG. 4 by area 311 on the substrate. The area 311 is additionally covered by the mask having deposition material 375 deposited on the mask. According to embodiments described herein, the mask or parts of the mask may be movable in order to compensate for the covering of area 311 on the substrate.

For long production times and during the lifetime of an edge exclusion mask, lots of deposited material collects on the mask. For instance, a thick layer of several millimeters thickness grows on the mask, and in particular on the boundary parts of the mask. FIG. 4 shows a schematic side view of an example of a mask 340 having an aperture 341. Deposition material 375 is deposited on the mask 340 during the deposition process. As used herein, the “former or original boundary” of the mask aperture is the boundary before the mask was subjected to deposition. In FIG. 4, the former or original boundary of the mask aperture 341 is indicated with reference number 360. The “newly formed boundary of the aperture” as used herein is denoted with 365 and is the boundary limiting the coating window of the mask after some time of material deposition. If the mask was already subjected to material deposition, the newly formed boundary of the aperture is formed from deposition material. According to embodiments, which can be combined with other embodiments described herein, the mask 340 includes portions, which can be moved with respect to each other in a direction parallel to the substrate 310, such that the coating window size can be adapted.

Generally, the boundary of the aperture should be understood as the boundary limiting the coating window of the mask, through which deposition material can pass to reach the substrate.

Typically, the more material is deposited on the mask, the more the area of the aperture decreases. The actual coating window, through which the deposition material can pass, becomes smaller during operation due to shadowing effects of the coated boundary part of the mask. In FIG. 4, the deposited material 375 provides an additional shadowing effect of the mask 340 on the area 311 of a substrate 310. The shadowing effect reduces the thickness of the coating on the substrate close to the edge of the substrate.

In production, the growing of the coating on the mask influences the deposition process. In particular, the growing of the deposition material influences the deposition process to an extent, where the required specification on thickness and resistance of the deposited material layer on the substrate or at least on parts of the substrate cannot be met anymore. To avoid this unsatisfactory coating, it is known in the art to remove and clean the mask or parts thereof. However, this requires an interruption of the coating process, which is both, time consuming and cost intensive.

In order to avoid the need of interrupting the deposition process, embodiments described herein provide a mask that allows for adjusting the size of the mask aperture dependent on characteristics of material deposited on the mask. By introducing an adjustable edge exclusion mask, it becomes possible to react on growing coating thickness on the edge exclusion mask in such a way that the coating window of the mask is kept constant.

Typically, keeping the coating window of the mask constant during deposition is achieved by driving the frame portions or mask parts away from each other. According to some embodiments, the mask parts or frame portions are driven continuously. According to embodiments, the portions of the mask can be moved incrementally, e.g. several microns every minute. For instance, the mask parts may be moved after a predetermined time period of depositing material. Typically, the velocity of driving the mask part or frame portion may be calculated based on a predetermined deposition rate and/or on experienced data. For instance, the parameters of a certain process are used to determine the deposition rate on the mask and, thus, the velocity of the frame portions. Typically, a look-up table may be used to determine the amount and speed of the movement of the frame portion or mask parts.

According to some embodiments, the movement of the mask parts may be calculated based on measurements of the deposited material layer on the mask. For instance, a characteristic, such as the thickness of the material layer on the mask, may be measured and the velocity of the mask parts may be calculated and/or determined based on the measurement.

Typically, the mask forms a frame having one or more frame portions with the aperture as the coating window. The mask can further include drives like motors or actuators, linear guides for control of the movement, linear actuators, one or more power supplies for providing power to the actuator or motor, a movement controller and/or means for receiving a signal for triggering the movement. In one embodiment, a controller includes look-up tables for controlling the movement of the frame portions. The frame portions of the mask adapted for being moved depending on the amount of deposition material can also be referred to as mask parts.

FIG. 5 shows an edge exclusion mask 400 according to embodiments described herein. Typically, the mask 400 has an aperture 415 surrounded by a frame 430, which exemplarily includes eight frame portions 401, 402, 403, 404, 405, 406, 407, and 408. According to some embodiments, the number of frame portions may vary dependent on further mask characteristics, such as overall size of the mask, design of the mask etc. For instance, the number of frame portions may be smaller than eight, such as two or four. According to some embodiments, the number of frame portions may be greater than eight, such as nine, ten, twelve, or even higher than twelve. According to some embodiments, only one portion of the frame is movable, whereby the rest of the frame is static. Typically, more than one frame portion is movable.

The substrate 410 is shown below the mask and the edges of the substrate 410 are shown in dashed lines. The substrate may be a substrate as described above. Typically, the substrate is a substrate to be coated.

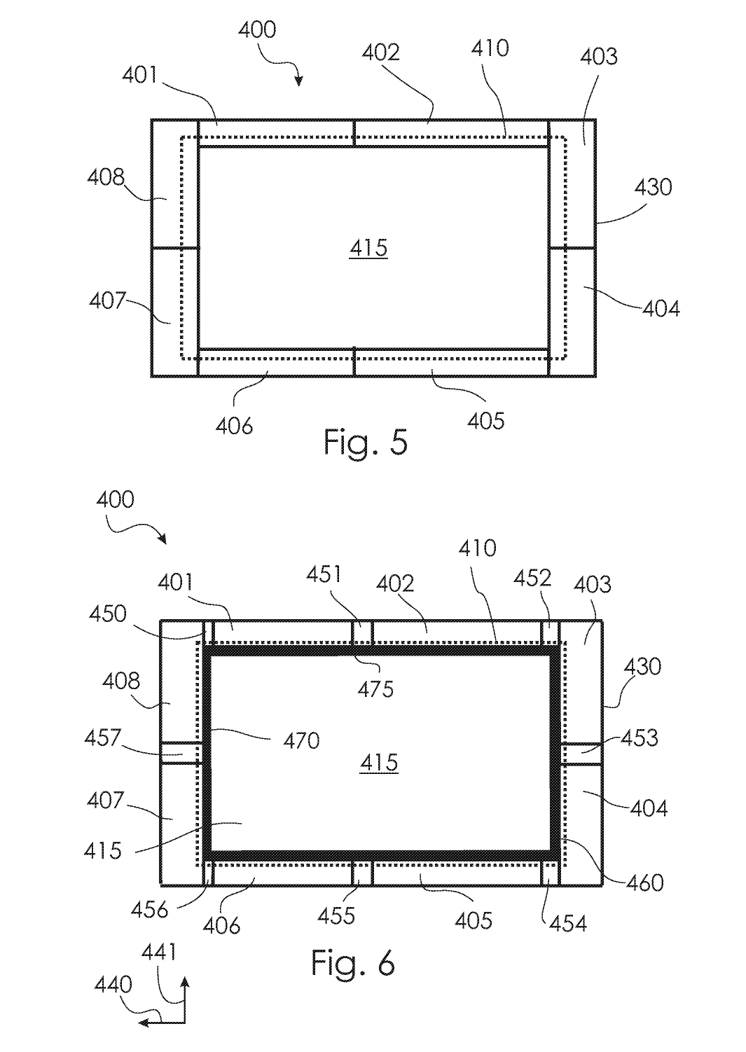

In FIG. 6, the edge exclusion mask 400 of FIG. 4 is shown after a time period of a deposition process. The single frame portions 401, 402, 403, 404, 405, 406, 407, and 408 are moved away from each other. Arrows 440 and 441 indicate the direction in which the frame portions are moved, either positively or negatively. According to some embodiments, all frame portions are moved in the same direction. For instance, each of the frame portions 401, 402, 403, 404, 405, 406, 407, and 408 are moved to the same extent in two directions. The case, where each frame portion is moved in two directions to the same extent, is shown in FIG. 6.

Generally, the mask according to embodiments described herein may have overlapping portions which are able to provide a cover for the substrate when frame portions are moved away from each other. For instance, the overlapping portions may overlap with the mask parts when the mask parts are not yet driven as is shown in FIG. 5. In case, the mask parts are driven away from each other, the overlapping portions may partially overlap with the mask parts, as described in detail with respect to FIG. 6. According to some embodiments, the size of the overlapping portions may be adapted to the gap which forms when the mask parts are moved with respect to each other. Typically, the gaps formed when the frame portions are moved away from each other are covered by overlapping portions of the mask.

In the embodiment of FIG. 6, overlapping portions 450, 451, 452, 453, 454, 455, 456, and 457 are shown covering the gap between the frame portions 401, 402, 403, 404, 405, 406, 407, and 408. Typically, the overlapping portions do not completely overlap with the frame portions anymore in case they cover the gap. However, for the sake of simplicity, portions 450, 451, 452, 453, 454, 455, 456, and 457 are referred to as overlapping portions. Again, the substrate 410 is shown in dashed lines. From FIG. 6, in particular when compared with FIG. 5, it can be seen that the boundary of the aperture of the mask 400 is moved with respect to the substrate 410. The former or original boundary is denoted with reference number 460. However, due to material deposition 470, there is a newly formed inner boundary 475 of the mask aperture. For the sake of simplicity, only a portion of the deposited material 470 is shown on the mask in the region of the aperture boundary. However, it should be understood that the material deposited on the mask extends over large parts of the mask.

Typically, the frame portions 401, 402, 403, 404, 405, 406, 407, and 408 may be arranged in a tongue-and-groove arrangement. The tongue-and-groove arrangement provides fixed positions of the frame portions relatively to one another. Further, according to some embodiments described herein, the tongue-and-groove arrangements of the frame portions allow the movement of the frame portions away from each other. Typically, a tongue-and-groove arrangement enables the frame portions to slide away from each other without causing a gap through which deposition material could pass. Thus, the tongues and grooves of the frame portions may be adapted to cover the area or gap between the frame portions, when the frame portions are moved.

According to some embodiments, the frame portions are adapted to be moved typically about 5 mm, more typically about 15 mm, and even more typically about 20 mm in either direction. According to some embodiments, the range of movement of the frame portions is dependent on the process for which the mask is designed. For instance, for some application, the range of movement may even be below 5 mm or above 20 mm.

Typically, in case where the edge of the substrate is about 5 mm and the frame portions are exemplarily moved 15 mm, the former or original boundary of the mask aperture may exceed the edge of the substrate. Nevertheless, due to the shadowing effects of the deposited material on the mask, the edge of the substrate remains free from deposition material as desired. Thus, the newly formed boundary of the mask aperture provides a coating window providing the desired edge exclusion on the substrate.

According to some embodiments, the frame portions of the edge exclusion mask may be moved in a range of typically about 0.03% to about 3%, more typically about 0.2% to about 2%, and even more typically about 0.5% to about 1% of an edge length of the substrate to be coated.

According to some embodiments, which can be combined with other embodiments described herein, the edge mask may be adapted to be moved to an extent, which allows performing the deposition process as long as the deposition material source is able to provide deposition material. For instance, one mask may be used without cleaning or maintenance interruption during one target lifetime. According to some embodiments, the mask is exchanged at the same time, when the material source is exchanged or refilled. With this approach, the deposition process is only interrupted when the deposition material is exhausted. No further limitation of the process speed due to mask cleaning is required.

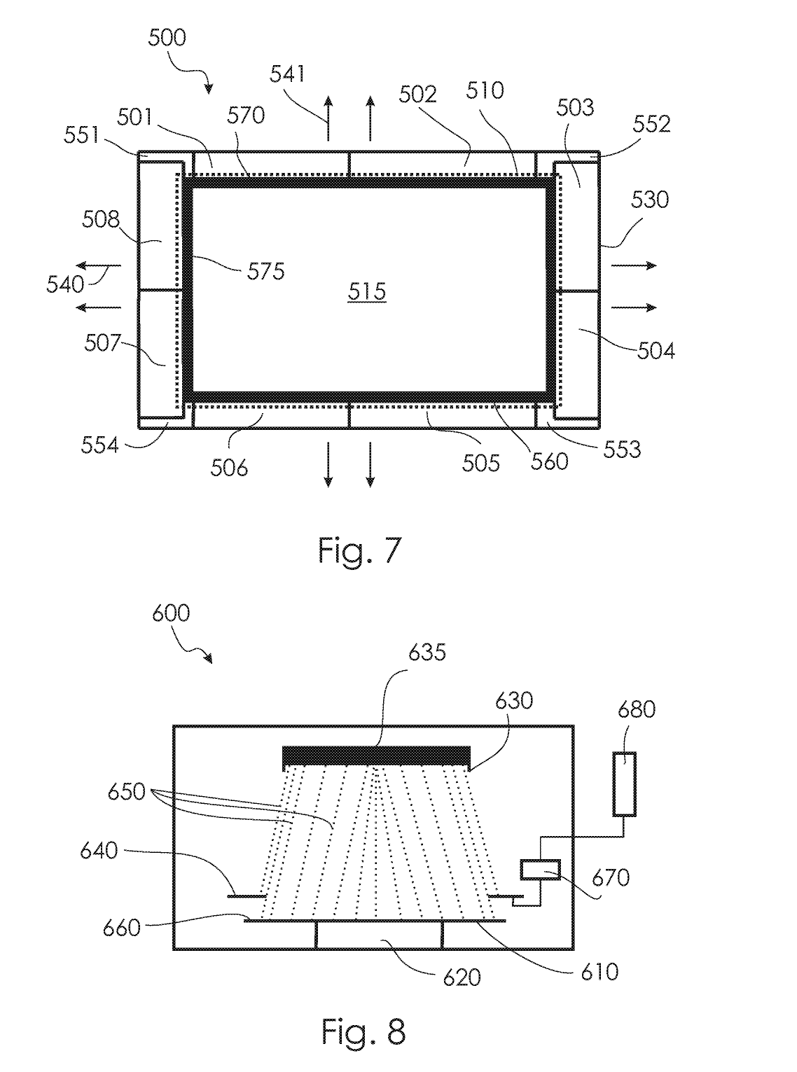

In FIG. 7, a mask 500 is shown according to some embodiments described herein. Typically, the mask includes an aperture 515, which is surrounded by frame portions. The mask 500 has exemplarily eight frame portions 501, 502, 503, 504, 505, 506, 507, and 508. The characteristics of the frame portions may be the same as described above with respect to FIG. 6. For instance, the number of the frame portions may vary or the connection of the frame portions may be provided by a tongue-and-groove arrangement.

As shown in FIG. 7, the frame portions 501, 502, 503, 504, 505, 506, 507, and 508 are each driven in one direction only, as indicated by arrows 540 and 541. Typically, gaps formed by the moving frame portions are covered by overlapping portions 551, 552, 553, and 554.

According to some embodiments, which can be combined with other embodiments described herein, the overlapping portions may be provided by the tongues of the tongue-and-groove arrangement of the frame portions. Typically, the frame portions are adapted to provide a sufficient tongue size. For instance, if the frame portions are moved for 10 mm, the tongue of the frame portions is greater than 10 mm in order to cover the gap and to provide a connection between the frame portions at the same time.

According to some embodiments, further connections or arrangements of the frame portions may be provided, which allow for covering the gap formed by the movement of the frame portion. For instance, there may be second frame parts beneath the frame portions, which are movable to cover the respective gaps.

Corresponding to FIG. 6, deposition material 570 is shown in FIG. 7 on the boundary of the mask aperture. The former boundary 560 does not provide the function of an aperture boundary anymore after some time of material deposition. Instead, newly formed boundary 575 provides the limitation of the coating window.

In FIG. 8, a deposition chamber according to embodiments described herein is shown. A material source 630 with deposition material 635 is provided. Typically, the deposition chamber may correspond to the deposition chamber described with respect to FIG. 2. The characteristics and properties described in FIG. 2 can be applied to the chamber 600. A substrate 610 is provided, being located on a substrate support 620. The mask 640 allows for coating the substrate 610 with material 650 within a coating window. An edge 660 of substrate 610 remains free of coating due to mask 640. Typically, mask 640 is a mask as described above with respect to FIGS. 5 to 7. For instance, the mask 640 is connected to a drive unit 670 for moving the frame portions of mask 640. Typically, the drive unit 670 is connected to a controller 680. According to some embodiments, the controller 680 may be located outside the deposition chamber 600. Typically, the controller 680 may control the drive unit 670 in a remote mode.

Typically, the frame portions may be located on guiding devices, such as rails or the like in order to assure precise alignment of the frame portions during and/or after moving.

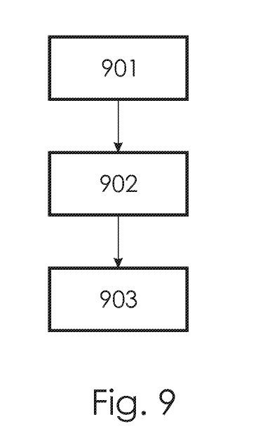

According to some embodiments, a method is provided for depositing a deposition material layer on a substrate. FIG. 9 shows a flow diagram of the described method. Typically, step 901 denotes providing a substrate in a deposition apparatus. According to some embodiments, the substrate may be a substrate as described above and the deposition apparatus may be a deposition chamber as exemplarily shown in FIG. 8.

In step 902, a part of the substrate is covered by a mask. Typically, the mask covers an edge of the substrate. Thus, the mask may be denoted as edge exclusion mask. According to some embodiments, the mask provides an aperture which allows deposition material to pass through during a deposition process. Examples of such a mask are described with respect to FIGS. 5 to 8.

During deposition or, alternatively, in a short deposition break, such as during change of substrate, the parts of the mask are moved, which is indicated by step 903. Typically, a frame of the mask includes several frame portions, which are moved. According to some embodiments, the frame portions are moved individually, i.e. independently from one another.

In step 903, the frame portions are typically moved depending on the deposition material deposited on the edge exclusion mask during the deposition process. For instance, the frame portions may be moved depending on predetermined characteristics of the deposited material, such as the thickness of the deposited material on the mask.

Typically, the frame portions are moved in a plane substantially parallel to the surface of the substrate to be coated with deposition material. According to some embodiments, the frame portions are moved in a plane in which the mask is arranged. For instance, if the mask is arranged substantially parallel to the substrate surface, the frame portions may be moved in a plane substantially parallel to the substrate surface. Thus, if the substrate is arranged horizontally in a deposition apparatus, the frame portions are also moved horizontally, or at least substantially horizontally. The same applies for vertically arranged substrates

According to some embodiments, the movement of the frame portions may be moved in a second movement direction, which is different from the movement in a plane parallel to the surface of the substrate to be coated. For instance, mask parts may be tilted or rotated with respect to the plane parallel to the substrate surface. Typically, a rotation or tilting of mask parts may help keeping a distance between the substrate and the mask having deposition material thereon constant.

Typically, the distance of the frame portions to each other increases when the frame portions are moved. Generally, this means that the distance between the central points of the geometry of the frame portions becomes greater during the deposition process, when the frame portions are moved.

According to some embodiments, the method for depositing material, deposition the apparatus and the mask for covering an edge of the substrate are used for large area substrates.

Typically, by moving the at least one frame portions, as described above, the boundary of the aperture of the mask can be adjusted. Thus, the coating window of the mask can be influenced to satisfy the given requirements regarding thickness and uniformity of the deposited material on the substrate. Further, the mask and the coating window of the mask may be adapted to special process criteria, such as chosen deposition material, deposition speed, material density and the like. According to some embodiments described herein, the adjustable edge exclusion mask allows reacting on growing coating thickness on the edge exclusion mask in such a way that the coating window is kept constant by continuously driving the frame portions of the edge exclusion mask away from each other.

Typically, an adjustable edge exclusion mask helps reducing maintenance steps during deposition, in particular, during one target lifetime. Therefore, production efficiency can be increased and down time of a deposition apparatus can be reduced. This saves time as well as costs.

According to embodiments described herein, a deposition apparatus for forming a deposition material layer on a substrate is provided. The deposition apparatus includes a substrate support adapted for holding a substrate; and an edge exclusion mask for covering a periphery of the substrate during layer deposition. Typically, the mask has at least one frame portion defining an aperture; wherein the at least one frame portion of the mask is adapted for being moved with respect to the substrate depending on the amount of deposition material deposited on the at least one frame portion of the mask.

Typically, the at least one frame portion is adapted to be moved in a plane substantially parallel to the surface of the substrate to be coated.

According to some embodiments, which can be combined with other embodiments described herein, the mask includes more than one frame portion.

Typically, the more than one frame portions are adapted to be moved individually from each other. That means that the more than one frame portions may be adapted to be controlled individually and are able to move independent from each other.

According to some embodiments, the aperture of the mask defines the area of the substrate which is subjected to layer deposition. Typically, the area of the substrate may be denoted as a coating window.

According to further embodiments, the area of the aperture is constant during layer deposition of a substrate. In accordance with the above, a constant aperture means a constant coating window during the lifetime of the mask in this context.

According to some embodiments, which can be combined with other embodiments described herein, the at least one frame portion is moved depending on the thickness of the deposition material layer on the mask.

Typically, the at least one frame portion is adapted to be moved in a range of about 0.2% to about 2% of the length of a substrate edge of the substrate on which a deposition material should be coated.

According to some embodiments, a method for depositing a deposition material layer on a substrate is provided. Typically, the method includes providing a substrate in a deposition apparatus; covering at least a part of the substrate with a mask having at least one frame portion defining an aperture; moving the at least one frame portion of the mask with respect to the substrate depending on the amount of deposition material deposited on the at least one frame portion of the mask.

According to some embodiments, the method further includes controlling the movement of the at least one frame portion depending on a characteristic of the deposition material deposited on the at least one frame portion of the mask. Typically, the characteristic is the thickness of the deposited material on the mask.

Typically, moving the at least one frame portion includes moving the at least one frame portion in a plane substantially parallel to the surface of the substrate.

According to some embodiments, which can be combined with other embodiments described herein, moving the at least one frame portion of the mask includes keeping the aperture of the mask substantially constant.

Typically, moving the at least one frame portion includes moving more than one frame portion of the mask and wherein the frame portions are moved so that the distance of the more than one frame portions to each other increases during moving.

According to some embodiments, a mask for a deposition apparatus for depositing a deposition material layer on a substrate is provided. Typically, the mask is adapted for covering a periphery of the substrate. The mask includes at least one frame portion defining an aperture; wherein the at least one frame portion of the mask is adapted for being moved with respect to the substrate depending on the amount of deposition material deposited on the at least one frame portion of the mask.

Typically, the mask is adapted to be used in a deposition apparatus as described above.

Examples of a substrate support having different frame portions is described in EP patent application No. 1998366 entitled “Substrate support, substrate processing device and method of placing a substrate” filed Apr. 27, 2007, which is incorporated herein by reference to the extent the applications are not inconsistent with this disclosure.

While the foregoing is directed to embodiments of the invention, other and further embodiments of the invention may be devised without departing from the basic scope thereof, and the scope thereof is determined by the claims that follow.

1. A deposition apparatus for forming a deposition material layer on a substrate comprising:
a substrate support adapted for holding a substrate; and
an edge exclusion mask for covering a periphery of the substrate during layer deposition, the mask having at least one frame portion defining an aperture;
wherein the at least one frame portion of the mask is adapted for being moved with respect to the substrate depending on the amount of deposition material deposited on the at least one frame portion of the mask.

2. The deposition apparatus according to claim 1, wherein the at least one frame portion is adapted to be moved in a plane substantially parallel to the surface of the substrate.

3. The deposition apparatus according to claim 1, wherein the mask comprises more than one frame portion.

4. The deposition apparatus according to claim 3, wherein the more than one frame portions are adapted to be moved individually from each other.

5. The deposition apparatus according to claim 1 wherein the aperture (341; 415; 515) defines the area of the substrate which is subjected to material deposition.

6. The deposition apparatus according to claim 1, wherein the area of the aperture is substantially constant during layer deposition on a substrate.

7. The deposition apparatus according to claim 1, wherein the at least one frame portion is moved depending on the thickness of the deposition material layer on the mask.

8. The deposition apparatus according to claims 1, wherein the at least one frame portion is adapted to be moved in a range of about 0.2% to about 2% of the length of a substrate edge of the substrate on which a deposition material should be coated.

9. Method for depositing a deposition material layer on a substrate comprising:
providing a substrate in a deposition apparatus;
covering at least a part of the substrate with a mask having at least one frame portion defining an aperture; and
moving the at least one frame portion of the mask with respect to the substrate depending on the amount of deposition material deposited on the at least one frame portion of the mask.

10. Method according to claim 9, further comprising controlling the movement of the at least one frame portion depending on a characteristic of the deposition material deposited on the at least one frame portion of the mask.

11. Method according to claim 9, wherein moving the at least one frame portion comprises moving the at least one frame portion in a plane substantially parallel to the surface of the substrate.

12. Method according to claim 11, wherein moving the at least one frame portion of the mask comprises keeping the aperture of the mask substantially constant.

13. Method according to claim 9, wherein moving the at least one frame portion comprises moving more than one frame portion of the mask and wherein the frame portions are moved so that the distance of the more than one frame portions to each other increases during moving.

14. Edge exclusion mask for a deposition apparatus for depositing a deposition material layer on a substrate, wherein the mask is adapted for covering a periphery of the substrate, the mask comprising:
at least one frame portion defining an aperture for allowing deposition material passing through onto the substrate;
wherein the at least one frame portion of the mask is adapted for being moved with respect to the substrate depending on the amount of deposition material layer deposited on the at least one frame portion of the mask.

15. Edge exclusion mask according to claim 14, wherein the mask is adapted to be used in a deposition apparatus for forming a deposition material layer on a substrate, the deposition apparatus comprising a substrate support adapted for holding a substrate.

16. The deposition apparatus according to claim 2, wherein the mask comprising more than one frame portion.

17. The deposition apparatus according to claim 16, wherein the more than one frame portions are adapted to be moved individually from each other.

18. The deposition apparatus according to claim 2, wherein the aperture defines the area of the substrate, which is subjected to material deposition.

19. Method according to claim 10, wherein moving the at least one frame portion comprises moving the at least one frame portion in a plane substantially parallel to the surface of the substrate.

20. A deposition apparatus for forming a deposition material on a substrate comprising:
a deposition source support for supporting a deposition source comprising the deposition material;
a substrate support for supporting the substrate to be processed in the deposition apparatus; and
an edge exclusion mask between the deposition source support and the substrate support, the edge exclusion mask including a frame for covering the edge of the substrate to be processed in the deposition apparatus, wherein the frame of the edge exclusion mask surrounds a coating window not covering the substrate during processing, the frame comprising movable portions and the deposition apparatus is adapted for driving the movable frame portions in dependence on the amount of deposition material on the frame of the edge exclusion mask so that the coating window of the edge exclusion mask remains substantially constant during processing.
